(19) United States
(12) Patent Application Publication
(10) Pub. No.: US 2023/0292484 A1
(43) Pub. Date: Sep. 14, 2023

(54) SEMICONDUCTOR DEVICE INCLUDING WRITE TRANSISTOR AND READ TRANSISTOR

(71) Applicant: SK hynix Inc., Icheon-si (KR)

(72) Inventor: Mir IM, Icheon-si (KR)

(21) Appl. No.: 17/875,397

(22) Filed: Jul. 27, 2022

(30) Foreign Application Priority Data
Mar. 14, 2022 (KR) 10-2022-0031716

(51) Int. Cl. H01L 27/108

(52) U.S. Cl. CPC H01L 27/108

(57) ABSTRACT

A semiconductor device according to an embodiment of the present disclosure includes a read transistor and a write transistor that are electrically connected to each other over a substrate. The read transistor includes a read channel layer disposed on a plane over the substrate, a read gate dielectric layer disposed over the read channel layer, and a read gate electrode layer disposed over the read gate dielectric layer. The write transistor includes a write channel layer disposed over a portion of the read gate electrode layer, a write bit line disposed on an upper surface of the write channel layer, a write gate dielectric layer on a side surface of the write channel layer, and a write word line disposed to be adjacent to the write gate dielectric layer.

### CROSS-REFERENCE TO RELATED APPLICATIONS

The present application claims priority under 35 U.S.C. § 119(a) to Korean Application No. 10-2022-0031716, filed on Mar. 14, 2022 in the Korean Intellectual Property Office, which is incorporated herein by reference in its entirety.

### BACKGROUND

### 1. Technical Field

The present disclosure generally relates to a semiconductor device, and more particularly, to a semiconductor device including a write transistor and a read transistor.

### 2. Related Art

As the size of a semiconductor memory device decreases, the space occupied by memory cells in the semiconductor memory device also decreases. Various studies are being conducted to maintain the degree of integration of memory cells in the reduced space.

For example, in the case of the conventional DRAM device, the memory cell employs a one-transistor and one-capacitor (1T-1C) structure in which one transistor and one capacitor are electrically connected. Recently, research has been conducted on reducing the size of the memory cell by reducing the physical size of the capacitor, which occupies a relatively large space in the memory cell, or by omitting the capacitor. Through these studies, the emergence of new and improved memory cells implementing higher cell density is expected.

### SUMMARY

A semiconductor device according to an embodiment of the present disclosure may include a read transistor and a write transistor that are electrically connected to each other over a substrate. The read transistor may include a read channel layer disposed on a plane over the substrate, a read gate dielectric layer disposed over the read channel layer, and a read gate electrode layer disposed over the read gate dielectric layer. The write transistor may include a write channel layer disposed over a portion of the read gate electrode layer, a write bit line disposed on an upper surface of the write channel layer, a write gate dielectric layer disposed on a side surface of the write channel layer, and a write word line disposed to be adjacent to the write gate dielectric layer.

A semiconductor device according to another embodiment of the present disclosure may include first and second unit semiconductor elements that are disposed adjacent to each other over a substrate. The first unit semiconductor element may include a first read transistor and a first write transistor that are electrically connected to each other. The second unit semiconductor element may include a second read transistor and a second write transistor that are electrically connected to each other. A first read gate electrode layer of the first read transistor and a second read gate electrode layer of the second read transistor may be disposed to be spaced apart from each other in a direction substantially perpendicular to a surface of the substrate. A first write channel layer of the first write transistor and a second write channel layer of the second write transistor may be disposed between the first read gate electrode layer and the second read gate electrode layer in the direction substantially perpendicular to the surface of the substrate.

### BRIEF DESCRIPTION OF THE DRAWINGS

FIG. 1 is a circuit diagram of a semiconductor device according to an embodiment of the present disclosure.

FIG. 2 is a cross-sectional view schematically illustrating a semiconductor device according to an embodiment of the present disclosure.

FIG. 3 is a cross-sectional view of the semiconductor device of FIG. 2 taken along line A-A′ and illustrated on an x-y plane.

FIG. 4 is a cross-sectional view of the semiconductor device of FIG. 2 taken along line B-B′ and illustrated on the x-y plane.

FIG. 5 is a graph illustrating a dielectric property of a dielectric material layer according to an embodiment of the present disclosure.

FIG. 6 is a cross-sectional view schematically illustrating a semiconductor device according to another embodiment of the present disclosure.

FIG. 7 is a cross-sectional view of the semiconductor device of FIG. 6 taken along line I-I′ and illustrated on an x-y plane.

FIG. 8 is a cross-sectional view of the semiconductor device of FIG. 6 taken along line II-II′ and illustrated on the x-y plane.

FIG. 9 is a cross-sectional view of the semiconductor device of FIG. 6 taken along line III-III′ and illustrated on the x-y plane.

FIG. 10 is a cross-sectional view of the semiconductor device of FIG. 6 taken along line IV-IV′ and illustrated on the x-y plane.

FIG. 11 is a cross-sectional view of the semiconductor device of FIG. 6 taken along line V-V′ and illustrated on the x-y plane.

FIG. 12 is a cross-sectional view of the semiconductor device of FIG. 6 taken along line VI-VI′ and illustrated on an x-z plane.

FIG. 13 is a cross-sectional view of the semiconductor device of FIG. 6 taken along line VII-VII′ and illustrated on the x-z plane.

FIG. 14 is a cross-sectional view schematically illustrating a semiconductor device according to another embodiment of the present disclosure.

FIG. 15 is a cross-sectional view of the semiconductor device of FIG. 14 taken along line LY-LY′ and illustrated on an x-y plane.

FIG. 16 is a cross-sectional view of the semiconductor device of FIG. 14 taken along line VZ-VZ′ and illustrated on the x-z plane.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

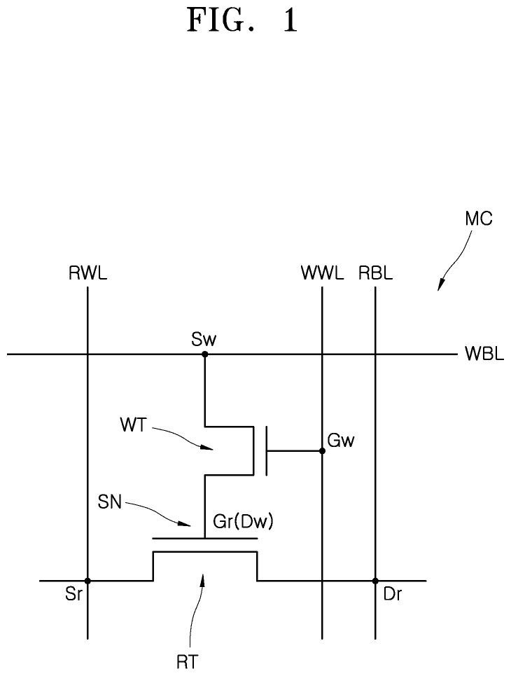

FIG. 1 is a circuit diagram of a semiconductor device according to an embodiment of the present disclosure. Referring to FIG. 1, a semiconductor device 1 may be a memory device including a memory cell MC. Compared to a memory cell of a conventional DRAM device, the memory cell MC might not include a capacitor element. The memory cell MC may include a write transistor WT and a read transistor RT that are electrically connected to each other.

The write transistor WT may include a write gate electrode Gw connected to a write word line WWL, and a write source electrode Sw connected to a write bit line WBL. The read transistor RT may include a read gate electrode Gr, a read source electrode Sr, and a read drain electrode Dr. The read source electrode Sr and the read drain electrode Dr may be connected to a read word line RWL and a read bit line RBL, respectively. A write drain electrode Dw of the write transistor WT may be electrically connected to the read gate electrode Gr of the read transistor RT.

In the memory cell MC in FIG. 1, a read gate dielectric layer SN of the read transistor RT may function as a storage dielectric layer storing signal information. In addition, the read gate electrode Gr of the read transistor RT may function as a storage electrode layer.

In an embodiment, a write operation in the memory cell MC may be performed as follows. The write transistor WT may be turned on or turned off according to a voltage signal applied to the write word line WWL. When the write transistor WT is turned on, an electrical signal of the write bit line WBL may pass through a channel of the write transistor WT, via the write drain electrode Dw, and may be applied to the read gate electrode Gr of the read transistor RT as a voltage level. For example, when a predetermined positive voltage signal is applied to the write bit line WBL in a state in which the write transistor WT is turned on, as electric charges are charged in the read gate dielectric layer SN, the voltage level of the read gate electrode Gr may be increased. Thereafter, the write transistor WT is turned off, and the read gate electrode Gr may maintain the increased voltage as a voltage of a first level. Accordingly, the memory cell MC may store the voltage state of the first level and a charge state of the electric charges as first signal information. As will be described later, when the read gate electrode Gr maintains the voltage of the first level, the read transistor RT may maintain a turned on state.

As another example, when a voltage of 0 V is applied to the 15 write bit line WBL in a state in which the write transistor WT is turned on, as the charges stored in the read gate dielectric layer SN are discharged to the write bit line WBL, the voltage level of the read gate electrode Gr may be decreased. Thereafter, the write transistor WT is turned off, and the read gate electrode Gr may maintain the decreased voltage level as a voltage of a second level. Accordingly, the memory cell MC may store the voltage state of the second level and the discharge state of the charges as second signal information. As will be described later, when the read gate electrode Gr maintains the voltage of the second level, the read transistor RT may maintain a turned off state.

In an embodiment, a read operation for the memory cell MC may be performed as follows. In a standby state, the read word line RWL and the read bit line RBL may maintain the same voltage level as zero (0 V). After the read operation begins, the voltage level of the read word line RWL may be increased to a predetermined positive voltage while the voltage level of the read bit line RBL is maintained at 0 V.

When the read gate electrode Gr maintains the voltage of the first level (i.e., when the memory cell MC stores the first signal information), the read transistor RT may maintain a turned on state. The read transistor RT may maintain the turned on state so that the voltage level of the read bit line RBL may be increased from 0 V. Alternatively, when the read gate electrode Gr maintains the voltage of the second level (i.e., when the memory cell MC stores the second signal information), the read transistor RT may maintain a turned off state, and the read bit line RBL may maintain the voltage level of 0 V.

The voltage level of the read bit line RBL of the memory cell MC, which changes depending on whether the read transistor RT is turned on or turned off, may be amplified using a sense amplifier, and the signal information stored in the memory cell MC may be identified by comparing the amplified voltage level with a reference voltage level.

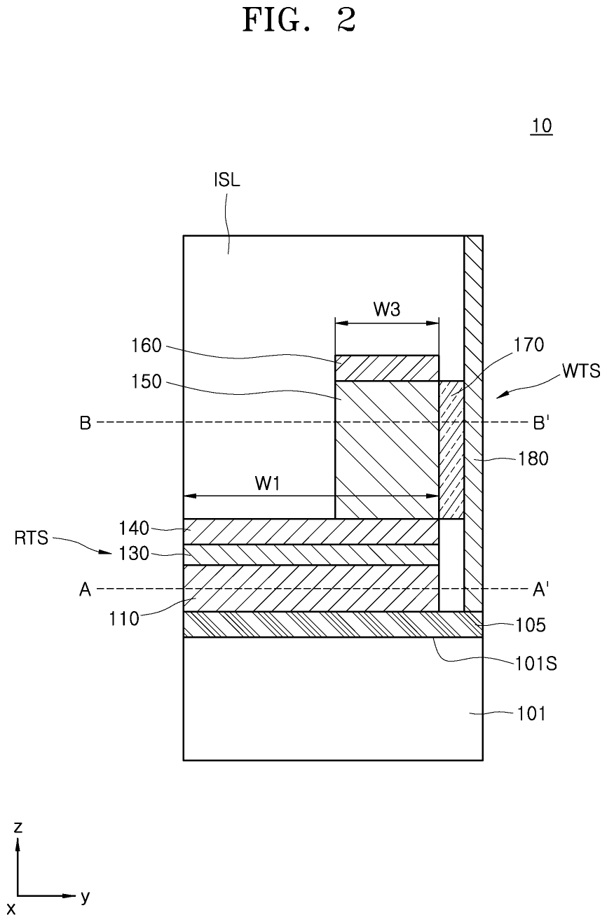

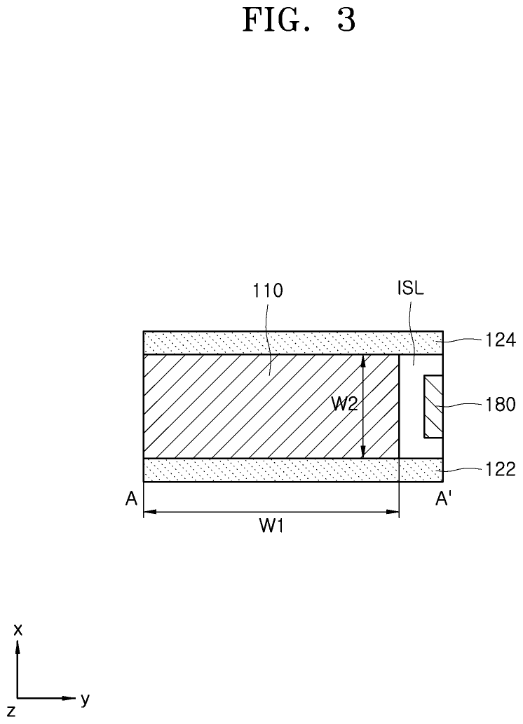

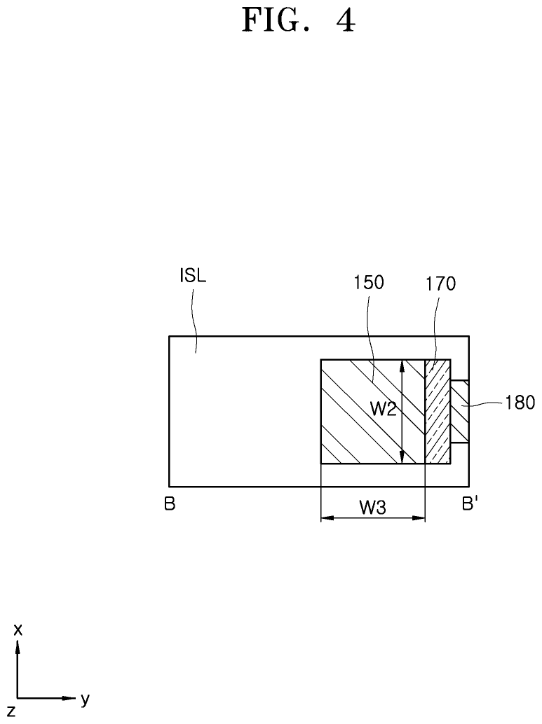

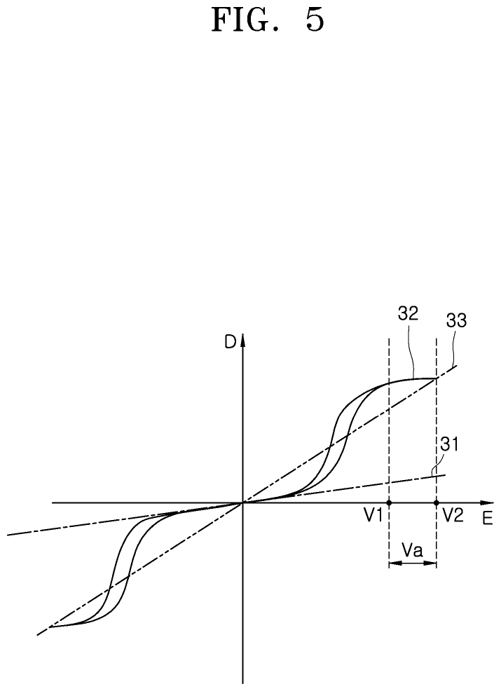

FIG. 2 is a cross-sectional view schematically illustrating a semiconductor device according to an embodiment of the present disclosure. FIG. 3 is a cross-sectional view of the semiconductor device of FIG. 2 taken along line A-A′ and illustrated on an x-y plane. FIG. 4 is a cross-sectional view of the semiconductor device 10 of FIG. 2 taken along line B-B′ and illustrated on the x-y plane. FIG. 5 is a graph illustrating a dielectric property of a dielectric material layer according to an embodiment of the present disclosure.

Referring to FIG. 2, a semiconductor device 10 may include a read transistor RTS and a write transistor WTS that are electrically connected to each other. The read transistor RTS and the write transistor WTS are arranged over a substrate 101 and may have circuit configurations of the read transistor RT and the write transistor WT of FIG. 1, respectively. The read transistor RTS and the write transistor WTS may constitute a memory cell MC of FIG. 1.

The read transistor RTS may include a read channel layer 110 disposed on a plane over the substrate 101, a read gate dielectric layer 130 disposed over the read channel layer 110, and a read gate electrode layer 140 disposed over the read gate dielectric layer 130. In addition, referring to FIG. 3, the read transistor RTS may include a read word line 122 and a read bit line 124 respectively disposed at opposite ends of the read channel layer 110.

The write transistor WTS may include a write channel layer 150 disposed over a portion of the read gate electrode layer 140, a write bit line 160 disposed on an upper surface of the write channel layer 150, a write gate dielectric layer 170 disposed on a side surface of the write channel layer 150, and a write word line 180 disposed adjacent to the write gate dielectric layer 170. As shown in FIGS. 2 and 4, the write word line 180 may be disposed on a side surface of the write gate dielectric layer 170.

Referring to FIG. 2, the semiconductor device 10 may further include an electrical insulation layer ISL surrounding the read transistor RTS and the write transistor WTS. Although not shown, the electrical insulation layer ISL may include a plurality of interlayer insulation layers. Each of the plurality of interlayer insulation layers may include an insulating material. For example, the insulating material may include oxide, nitride, oxynitride, or a combination of two or more thereof.

Referring to FIG. 2, the substrate 101 may include a semiconductor material. Specifically, the semiconductor material may include silicon (Si), germanium (Ge), gallium arsenide (GaAs), molybdenum sulfide (MoW₂), molybdenum selenide (MoSe2), hafnium selenide (HfSe₂), indium selenide (InSe), gallium selenide (GaSe), black phosphorus, indium-gallium-zinc oxide (IGZO), or a combination of two or more thereof. The substrate 101 may be doped with an n-type or p-type dopant to have conductivity.

Although not shown in FIG. 2, the substrate 101 may be electrically connected to the write word line 180. In addition, the substrate 101 may include integrated circuits. The integrated circuits may be circuits for driving and controlling memory cells. The integrated circuits may include, for example, devices such as diodes or transistors.

A base insulation layer 105 may be disposed over the substrate 101. The base insulation layer 105 may include, for example, oxide, nitride, oxynitride, or a combination of two or more thereof. Although not shown in FIG. 2, at least one conductive layer may be disposed between the substrate 101 and the base insulation layer 105. The conductive layer may function as a wiring for connecting different integrated circuits of the substrate 101 or a wiring for connecting the integrated circuits and the memory cell.

The read channel layer 110 may be disposed over the base insulation layer 105. The read channel layer 110 may be disposed on a surface substantially parallel to a surface 101S of the substrate 101. The read channel layer 110 may include a semiconductor material. The semiconductor material may include, for example, doped silicon (Si), doped germanium (Ge), doped gallium arsenide (GaAs), or the like. As another example, the semiconductor material may include a two-dimensional semiconductor material. The two-dimensional semiconductor material may include transition metal dichalcogenide (TMDC), black phosphorus, or the like. The transition metal dichalcogenide may include, for example, molybdenum selenide (MoSe₂), hafnium selenide (HfSe₂), indium selenide (InSe), gallium selenide (GaSe), or the like. As another example, the semiconductor material may include a conductive metal oxide. The conductive metal oxide may include indium oxide (In₂O₃), dopant-doped indium oxide (In₂O₃), indium gallium zinc oxide (InGaZnO₄), zinc oxide (ZnO), indium gallium oxide (InGaO₃), or the like. The dopant may include titanium (Ti), tungsten (W), silicon (Si), or a combination of two or more thereof.

Referring to FIGS. 2 and 3, the read channel layer 110 may have a first width W1 of a predetermined size in a first direction (e.g., the y-direction) that is substantially parallel to the surface 101S of the substrate 101. In addition, the read channel layer 110 may have a second width W2 of a predetermined size in a second direction (e.g., the x-direction) that is perpendicular to the first direction. Accordingly, in FIG. 3, the read channel layer 110 may have a rectangular cross-sectional shape.

In addition, the read word line 122 and the read bit line 124 at both ends of the read channel layer 110 may extend respectively in the first direction (e.g., the y-direction). The read word line 122 and the read bit line 124 may be disposed to be spaced apart from each other in the second direction (e.g., the x-direction). Accordingly, between the read word line 122 and the read bit line 124, conductive carriers may conduct through the read channel layer 110 in the second direction (e.g., the x-direction).

Each of the read word line 122 and the read bit line 124 may include a conductive material. The conductive material may include, for example, doped semiconductor, metal, conductive metal nitride, conductive metal carbide, conductive metal silicide, or conductive metal oxide. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIG. 2 again, the read gate dielectric layer 130 may be disposed over the read channel layer 110. The read gate dielectric layer 130 and the read channel layer 110 may be disposed to overlap with each other in a third direction (e.g., the z-direction), which is substantially perpendicular to the surface 101S of the substrate 101. Accordingly, the read gate dielectric layer 130 may have a first width W1 in the first direction (e.g., the y-direction) and a second width W2 in the second direction (e.g., the x-direction).

The read gate dielectric layer 130 may have a high dielectric constant. In an embodiment, the read gate dielectric layer 130 may include an anti-ferroelectric material. In another embodiment, the read gate dielectric layer 130 may include a paraelectric material having a high dielectric constant.

FIG. 5 schematically illustrates dielectric displacement D generated when an electric field is applied to various dielectric material layers. The dielectric displacement D may mean a surface charge density of a capacitor including each of the various dielectric material layers, and may be proportional to the permittivity of each of the various dielectric material layers. A first graph 31 may correspond to a paraelectric layer having a low dielectric constant, a second graph 32 may correspond to a dielectric layer including an antiferroelectric material, and a third graph 33 may correspond to a paraelectric layer having a high dielectric constant. Referring to the second graph 32, the dielectric layer including the antiferroelectric material may have a high dielectric constant due to strong polarization characteristics, but unlike a layer including a ferroelectric material, might not have remanent polarization. Referring to the second and third graphs 32 and 33, a dielectric layer including an antiferroelectric material may have a high dielectric constant similar to the paraelectric layer having a high dielectric constant. In an embodiment, a dielectric layer including the antiferroelectric material may secure a higher dielectric constant than that of the paraelectric layer within a predetermined operation voltage range Va. The predetermined operation voltage range Va may be the voltage range between a first voltage V1 and a second voltage V2 of FIG. 5, and may be a voltage range in which a dielectric layer including the antiferroelectric material has a substantially saturated dielectric displacement D.

The antiferroelectric material may include, for example, zirconium oxide (ZrO₂) having a tetragonal crystal structure, silicon-doped hafnium oxide (Si-doped HfO₂), silicon-doped hafnium zirconium oxide (Si-doped Hf_{0.5}Zr_{0.5}O₂), or a combination of two or more thereof. The paraelectric material having a high dielectric constant may include, for example, hafnium oxide (HfO₂), zirconium oxide (ZrO₂), hafnium zirconium oxide ((Hf,Zr)O₂), hafnium oxynitride (HfON), hafnium zirconium oxynitride (HfZrON)), barium strontium titanium oxide ((Br,Sr)TiO₃), lead zirconium titanium oxide ((Pb, Zr)TiO₃), or the like.

Referring to FIG. 2 again, the read gate electrode layer 140 may be disposed over the read gate dielectric layer 130. The read gate electrode layer 140 may be disposed to overlap with the read channel layer 110 and the read gate dielectric layer 130 in the third direction (e.g., the z-direction). Accordingly, the read gate electrode layer 140 may have the first width W1 in the first direction (e.g., the y-direction) and the second width W2 in the second direction (e.g., the x-direction). In an embodiment, the read channel layer 110, the read gate dielectric layer 130, and the read gate electrode layer 140 may be disposed on planes that are substantially parallel to the surface 101S of the substrate 101.

The read gate electrode layer 140 may include a conductive material. The conductive material may include, for example, doped semiconductor, metal, conductive metal nitride, conductive metal carbide, conductive metal silicide, or conductive metal oxide. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIG. 2, the write channel layer 150 may be disposed over a portion of the read gate electrode layer 140. Referring to FIG. 4, the write channel layer 150 may have a first width W3 in the first direction (e.g., the y-direction) and a second width W2 in the second direction (e.g., the x-direction). The first width W3 of the write channel layer 150 may be less than the first width W1 of the read gate electrode layer 140. Accordingly, a cross-sectional area (i.e., the first width W3*the second width W2) of the write channel layer 150 on a cross-sectional plane (i.e., the x-y plane) that is substantially parallel to the surface 101S of the substrate 101 may be less than an x-y plane cross-sectional area (i.e., the first width W1* the second width W2) of the read gate electrode layer 140. In addition, the write channel layer 150 may be overlapped with the read gate electrode layer 140 in the third direction (e.g., the z-direction). The cross-sectional area of the write channel layer 150 on an x-y plane may be located within the cross-sectional area of the read gate electrode layer 140 on an x-y plane.

The write channel layer 150 may be arranged on the read gate electrode layer 140 and may extend in the z-direction. Accordingly, the write channel layer 150 may have a shape of a rectangular pillar over the substrate 101.

The write channel layer 150 may include a semiconductor material. The semiconductor material may be substantially the same as the semiconductor material included in the read channel layer 110.

The write bit line 160 may be disposed over the write channel layer 150. In an embodiment, the write bit line 160 may contact the upper surface of the write channel layer 150 of the rectangular pillar shape. The write bit line 160 may be electrically connected to the write channel layer 150. The write bit line 160 may extend in the second direction (e.g., the x-direction). The write bit line 160 may include a conductive material. The conductive material of the write bit line 160 may be substantially the same as the conductive material of the read bit line 124.

The write gate dielectric layer 170 may be disposed adjacent to a side surface of the write channel layer 150. In an embodiment, the write gate dielectric layer 170 may be disposed to be in contact with the side surface of the write channel layer 150.

The write gate dielectric layer 170 may include a dielectric material. The dielectric material may include, for example, silicon oxide, silicon nitride, silicon oxynitride, aluminum oxide, hafnium oxide, zirconium oxide, or a combination of two or more thereof. In an embodiment, the write gate dielectric layer 170 may be made of substantially the same material as the read gate dielectric layer 130.

The write word line 180 may be disposed on a side surface of the write gate dielectric layer 170. The write word line 180 may extend in the third direction (e.g., the z-direction). The write word line 180 may have a pillar structure. Referring to FIGS. 2 to 4, the pillar structure may have a shape of a rectangular pillar, but is not necessarily limited thereto, and may have as examples a shape of a polygonal pillar, a cylinder, or an elliptical pillar other than the rectangular pillar. The write word line 180 may include a conductive material. The write word line 180 may be made of substantially the same material as the read word line 122.

Referring back to FIG. 2, in the write transistor WTS, a conductive channel may be formed in the write channel layer 150 along the third direction (e.g., the z-direction) by a voltage applied through the write word line 180. Conductive carriers may conduct along the conductive channel from the write bit line 160 to the read gate electrode layer 140.

The conductive carriers reaching the read gate electrode layer 140 may be charged in the read gate dielectric layer 130. The conductive carriers charged in the read gate dielectric layer 130 may be stored as signal information. The voltage level of the read gate electrode layer 140 may be changed according to the charging of the conductive carriers.

The changed voltage level may change a threshold voltage of the read channel layer 110 located between the read word line 122 and the read bit line 124. During a read operation of the semiconductor device 10, the signal information stored in the read gate dielectric layer 130 may be read by applying a read voltage between the read word line 122 and the read bit line 124 and measuring the change in the threshold voltage.

According to the above-described embodiment of the present disclosure, the read gate dielectric layer 130 may include an antiferroelectric material or a paraelectric material having a high dielectric constant. In addition, the read gate electrode layer 140 may be configured to have a surface area greater than that of the write channel layer 150 in contact with the surface of the read gate electrode layer 140. Accordingly, the surface areas of the read gate dielectric layer 130 and the read channel layer 110 that overlap in the z-direction with the read gate electrode layer 140 may also be greater relative to the write channel layer 150. As a result, the capacitance of the read gate dielectric layer 130 in the read transistor RTS may be effectively increased.

The capacitance of the read gate dielectric layer 130 is increased, so the retention of the signal information stored in the read gate dielectric layer 130 may be improved. In addition, as the capacitance of the read gate dielectric layer 130 is increased, a channel current passing through the read channel layer 110 may increase in a state in which the read transistor RTS is turned on. As the channel current increases, the read operation speed of the read transistor RTS may be improved. Accordingly, the memory performance of the semiconductor device 10 may be improved.

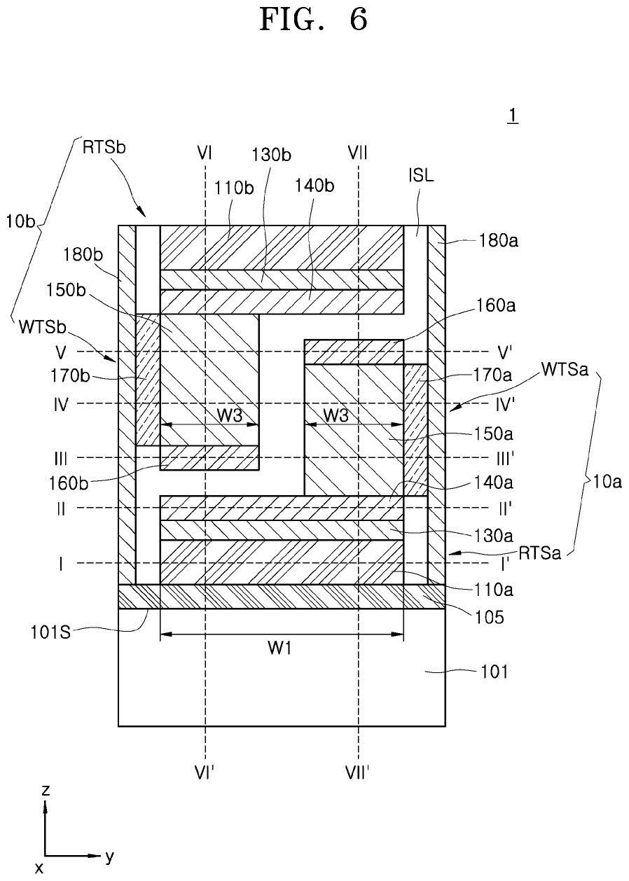

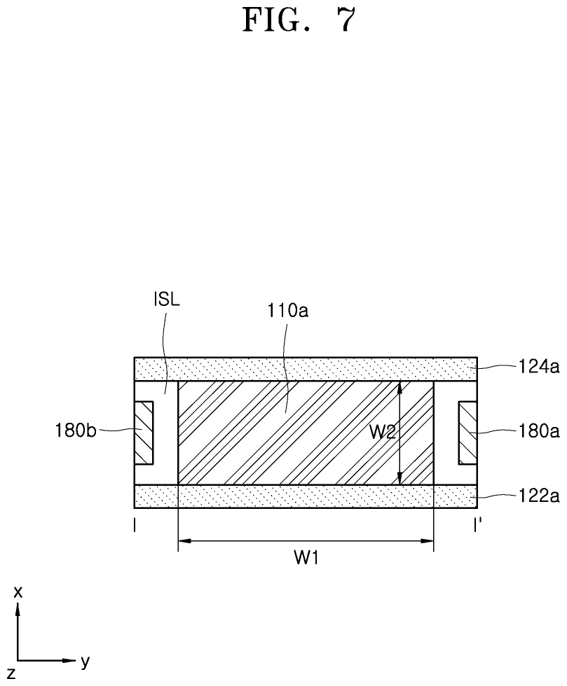

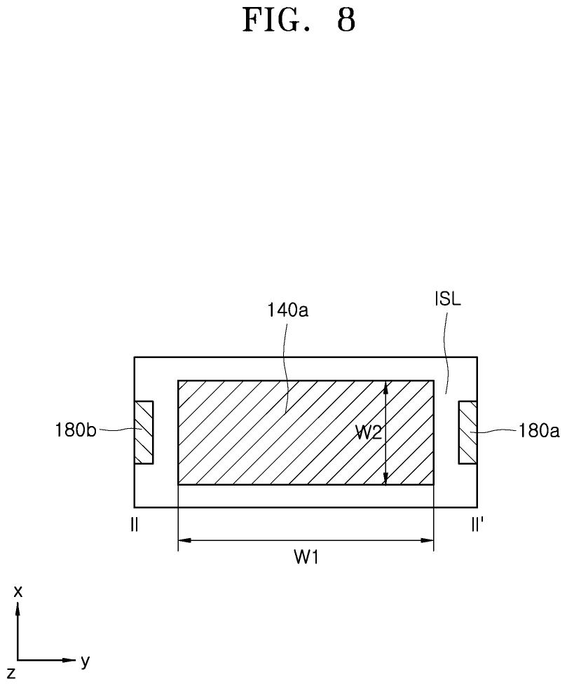

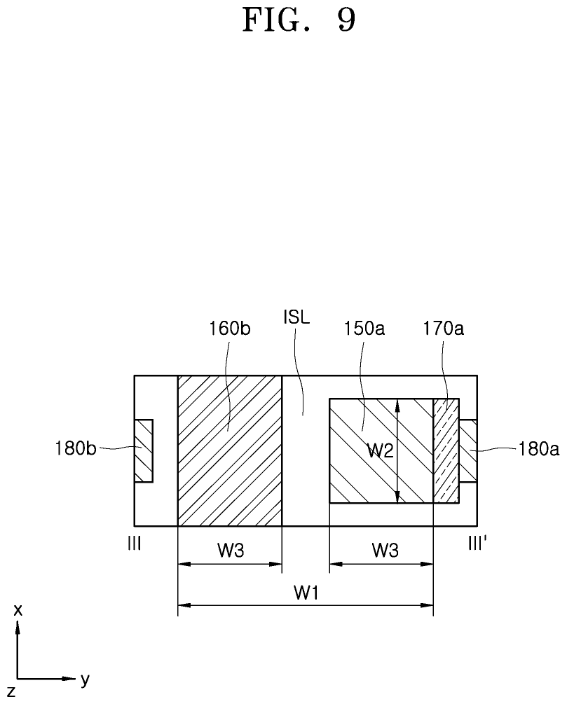

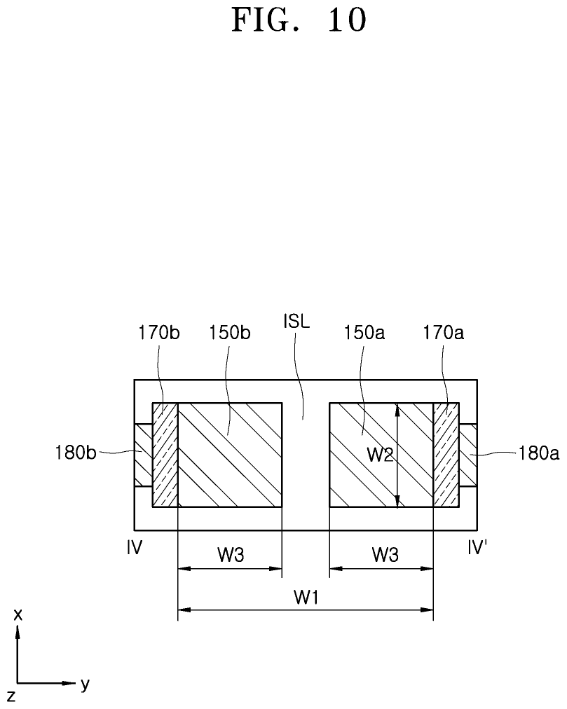

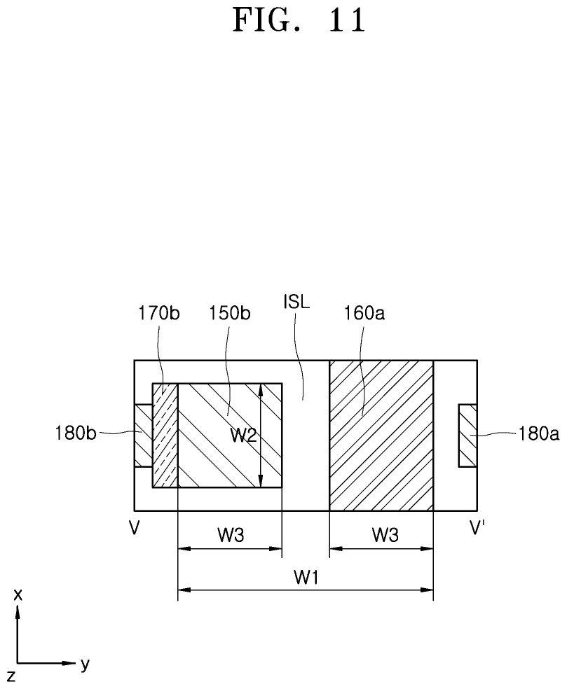

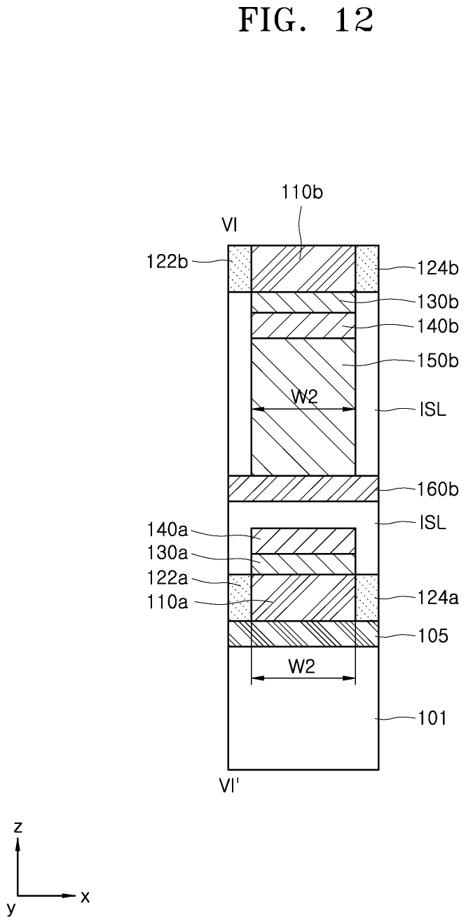

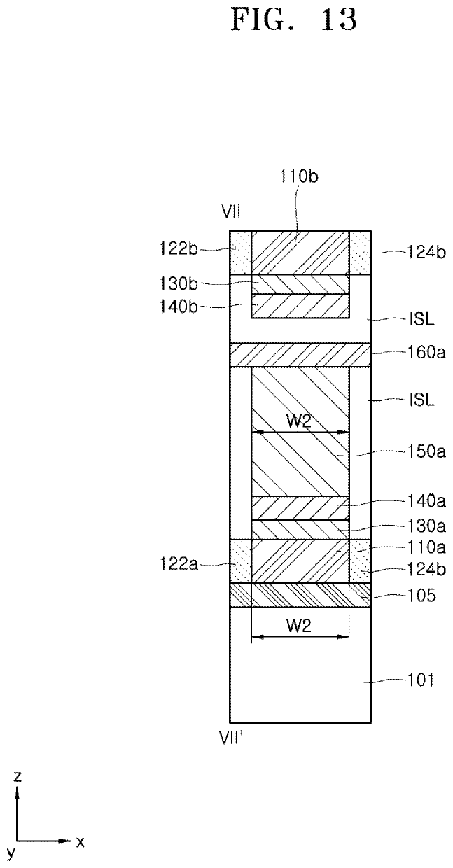

FIG. 6 is a cross-sectional view schematically illustrating a semiconductor device according to another embodiment of the present disclosure. FIG. 7 is a cross-sectional view of the semiconductor device of FIG. 6 taken along line I-I′ on an x-y plane. FIG. 8 is a cross-sectional view of the semiconductor device of FIG. 6 taken along line II-II′ on the x-y plane. FIG. 9 is a cross-sectional view of the semiconductor device of FIG. 6 taken along line III-III′ on the x-y plane. FIG. 10 is a cross-sectional view of the semiconductor device of FIG. 6 taken along line IV-IV′ on the x-y plane. FIG. 11 is a cross-sectional view of the semiconductor device of FIG. 6 taken along line V-V′ on the x-y plane. FIG. 12 is a cross-sectional view of the semiconductor device of FIG. 6 taken along line VI-VI′ on an x-z plane. FIG. 13 is a cross-sectional view of the semiconductor device of FIG. 6 taken along line VII-VII′ on the x-z plane.

Referring to FIG. 6, a semiconductor device 1 may include first and second unit semiconductor elements 10a and 10b that are disposed adjacent to each other over a substrate 101. Each of the first and second unit semiconductor elements 10a and 10b may be substantially the same as the semiconductor device 10 described above with reference to FIGS. 2 to 5. Each of the first and second unit semiconductor elements 10a and 10b may constitute the circuit of a memory cell MC of FIG. 1.

The first unit semiconductor element 10a may include a first read transistor RTSa and a first write transistor WTSa that are electrically connected to each other. Referring to FIGS. 6 to 13, the first read transistor RTSa of the first unit semiconductor element 10a may include a first read channel layer 110a disposed on a surface substantially parallel to a surface 101S of the substrate 101, a first read gate dielectric layer 130a disposed over the first read channel layer 110a, a first read gate electrode layer 140a disposed over the first read gate dielectric layer 130a, and a first read word line 122a and a first read bit line 124a that are disposed to respectively contact opposite surfaces of the first read channel layer 110a. Each of the first read word line 122a and the first read bit line 124a may extend in a first direction (e.g., the y-direction), which that is substantially parallel to the surface 101S of the substrate 101.

Referring to FIGS. 6 to 13, the first write transistor WTSa of the first unit semiconductor element 10a may include a first write channel layer 150a disposed over a portion of the first read gate electrode layer 140a and extending in a third direction (e.g., the z-direction), which is substantially perpendicular to the surface 101S of the substrate 101, a first write bit line 160a disposed on an upper surface of the first write channel layer 150a and extending in a second direction (e.g., the x-direction) that is substantially parallel to the surface 101S of the substrate 101, a first write gate dielectric layer 170a disposed on a side surface of the first write channel layer 150a, and a first write word line 180a disposed on the first write gate dielectric layer 170a and extending in the third direction (e.g., the z-direction).

The second unit semiconductor element 10b may include a second read transistor RTSb and a second write transistor WTSb that are electrically connected to each other. Referring to FIGS. 6 to 13, the second read transistor RTSb of the second unit semiconductor element 10b may include a second read channel layer 110b disposed on a surface that is substantially parallel to the surface 101S of the substrate 101, a second read gate dielectric layer 130b disposed over the second read channel layer 110b, a second read gate electrode layer 140b disposed over the second read gate dielectric layer 130b, and a second read word line 122b and a second read bit line 124b that are disposed to respectively contact opposite surfaces of the second read channel layer 110b. Each of the second read word line 122b and the second read bit line 124b may extend in the first direction (e.g., the y-direction).

The second write transistor WTSb of the second unit semiconductor element 10b may include a second write channel layer 150b disposed over a portion of the second read gate electrode layer 140b and extending in the third direction (e.g., the z-direction), a second write bit line 160b disposed on an upper surface of the second write channel layer 150b and extending in the second direction (e.g., the x-direction), a second write gate dielectric layer 170b disposed on a side surface of the second write channel layer 150b, and a second write word line 180b disposed on the second write gate dielectric layer 170b and extending in the third direction (e.g., the z-direction).

Referring back to FIG. 6, the first unit semiconductor element 10a and the second unit semiconductor element 10b, which are disposed on different planes, may at least partially overlap with each other with respect to the first direction (e.g., the y-direction) and the third direction (e.g., the z-direction).

The first read gate electrode layer 140a of the first read transistor RTSa and the second read gate electrode layer 140b of the second read transistor RTSb may be disposed to face each other in the third direction (e.g., the z-direction). The first read gate electrode layer 140a and the second read gate electrode layer 140b may overlap each other while being spaced apart from each other in the third direction (e.g., the z-direction). As a result, each of the first and second read gate electrode layers 140a and 140b may have a first width W1 in the first direction (e.g., the y-direction) and a second width W2 in the second direction (e.g., the x-direction).

The first write channel layer 150a of the first write transistor WTSa and the second write channel layer 150b of the second write transistor WTSb may be disposed in a space between the first and second read gate electrode layers 140a and 140b in the third direction (e.g., the z-direction).

Referring to FIG. 10, each of the first and second write channel layers 150a and 150b may have a third width W3 in the first direction (e.g., the y-direction) and the second width W2 in the second direction (e.g., the x-direction). Referring back to FIG. 6, the first and second write channel layers 150a and 150b may partially overlap with each other while being spaced apart from each other in the first direction (e.g., the y-direction).

Referring to FIGS. 6, 8, 10, 12, and 13, the first write channel layer 150a may be disposed over a portion of the first read gate electrode layer 140a, and the second write channel layer 150b may be disposed over a portion of the second read gate electrode layer 140b. Accordingly, the cross-sectional area (i.e., first width W1*second width W2) of the first read gate electrode layer 140a on a cross-sectional plane substantially parallel to the surface 101S of the substrate 101 may be greater than the cross-sectional area (i.e., third width W3*second width W2) of the first write channel layer 150a. The cross-sectional area (i.e., first width W1*second width W2) of the second read gate electrode layer 140b on an x-y plane may be greater than the cross-sectional area (i.e., third width W3*second width W2) of the second write channel layer 150b on an x-y plane.

The cross-sectional area on an x-y plane of each of the first and second read gate electrode layers 140a and 140b may be greater than the sum of the cross-sectional area of the first write channel layer 150a and the cross-sectional area of the second write channel layer 150b. Further, the first write channel layer 150a and the second write channel layer 150b may be overlapped with the first read gate electrode layer 140a and the second read gate electrode layer 140b in the z-direction. The cross-sectional areas of the first write channel layer 150a and the second write channel layer 150b on an x-y plane may be located within the cross-sectional area of the first read gate electrode layer 140a on an x-y plane or within the cross-sectional area of the second read gate electrode layer 140b on an x-y plane.

Referring to FIGS. 6, 9, and 11 to 13, the first write bit line 160a may be disposed over the first write channel layer 150a and may extend in the second direction (e.g., the x-direction). In addition, the second write bit line 160b may be disposed over the second write channel layer 150b and may extend in the second direction (e.g., the x-direction).

The first write bit line 160a may face the second read gate electrode layer 140b that is disposed to be spaced apart from the first write bit line 160a in the third direction (e.g., the z-direction). The first write bit line 160a may be disposed to cross the second read gate electrode layer 140b by extending in the x-direction. Meanwhile, the second write bit line 160b may face the first read gate electrode layer 140a that is disposed to be spaced apart from the second write bit line 160b in the third direction (e.g., the z-direction). The second write bit line 160b may be disposed to cross the first read gate electrode layer 140a by extending in the x-direction.

As described above, the first and second unit semiconductor elements 10a and 10b may be disposed adjacent to each other over the substrate 101. The first and second unit semiconductor elements 10a and 10b may be disposed between the first write word line 180a and the second write word line 180b along the first direction (e.g., the y-direction). In addition, the first and second read gate electrode layers 140a and 140b of the first and second unit semiconductor elements 10a and 10b, respectively, may be disposed to be spaced apart from each other in the third direction (i.e., the z-direction), and the first and second write channel layers 150a and 150b may be disposed in the space between the first and second read gate electrode layers 140a and 140b. The three-dimensional arrangement of the first and second unit semiconductor elements 10a and 10b described above provides a semiconductor device with an increased density of memory cells.

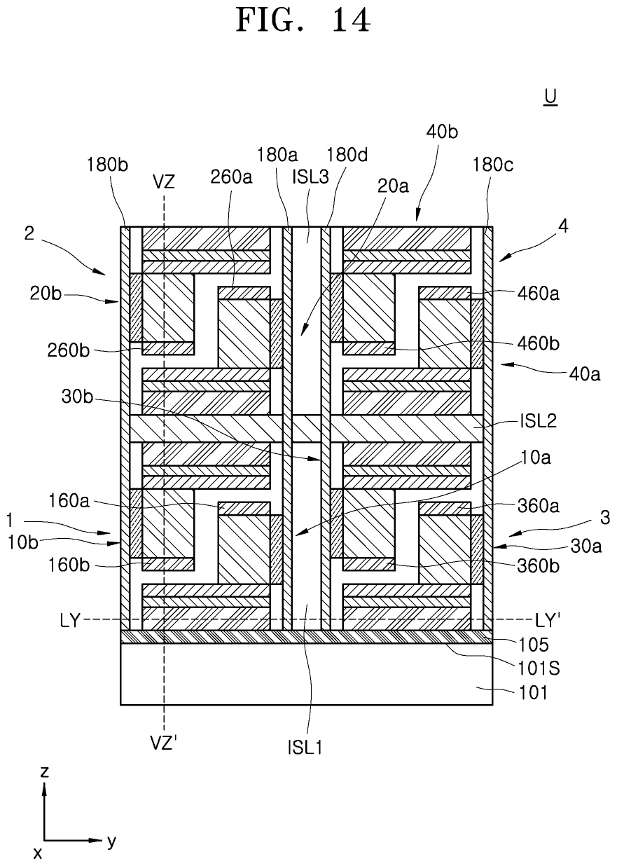

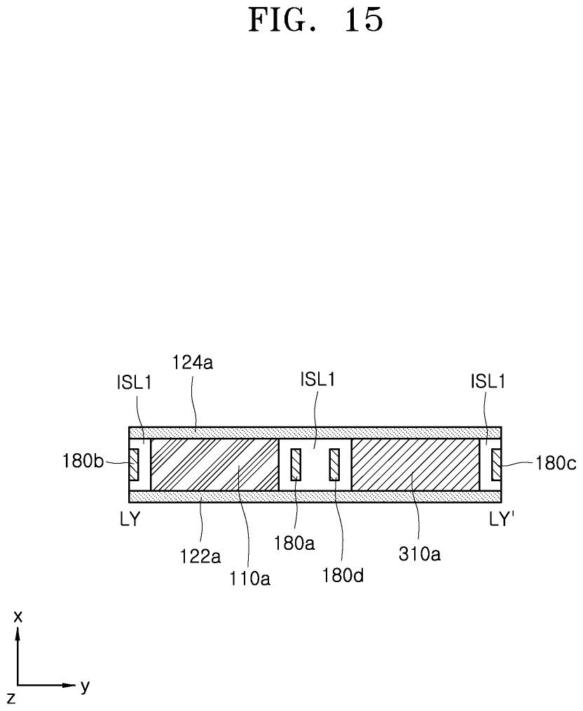

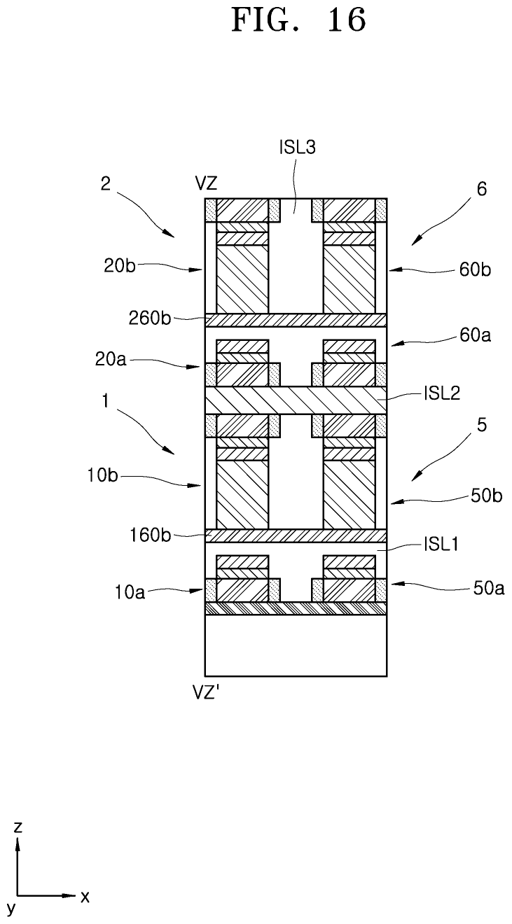

FIG. 14 is a cross-sectional view schematically illustrating a semiconductor device according to another embodiment of the present disclosure. FIG. 15 is a cross-sectional view of the semiconductor device of FIG. 14 taken along line LY-LY′ on an x-y plane. FIG. 16 is a cross-sectional view of the semiconductor device of FIG. 14 taken along line VZ-VZ′ on an x-z plane.

Referring to FIGS. 14 to 16, a semiconductor device U may be an array of first to eighth semiconductor devices 1-8. Each of the first to eighth semiconductor devices 1-8 may have substantially the same configuration as a semiconductor device 1 described above with reference to FIGS. 6 to 13. First to third insulation layers ISL1, ISL2, and ISL3 may be disposed between the first to eighth semiconductor devices 1-8. Each of the first to third insulation layers ISL1, ISL2, and ISL3 may include a well-known insulating material.

Referring to FIG. 14, the first semiconductor device 1 may include a first unit semiconductor element 10a and a second unit semiconductor element 10b. The second semiconductor device 2 may be disposed over the first semiconductor device 1 in a third direction (e.g., the z-direction). A second semiconductor device 2 may be electrically insulated or separated from the first semiconductor device 1 by the second insulation layer ISL2.

The semiconductor device 2 may include a first unit semiconductor element 20a and a second unit semiconductor element 20b. The first unit semiconductor element 20a of the second semiconductor device 2 may share the write word line 180a with the first unit semiconductor element 10a of the first semiconductor device 1. In addition, the first unit semiconductor element 10a and the first unit semiconductor element 20a may include write bit lines 160a and 260a respectively. Each of the first unit semiconductor element 10a and the first unit semiconductor element 20a may include a different read word line (not shown) and a different read bit line (not shown). Similarly, the second unit semiconductor element 20b of the second semiconductor device 2 may share the write word line 180b with the second unit semiconductor element 10b of the first semiconductor device 1. In addition, the second unit semiconductor element 10b and the second unit semiconductor element 20b may include write bit lines 160b and 260b respectively. Each of the second unit semiconductor element 10b and the second unit semiconductor element 20b may include a different read word line (not shown) and a different read bit line (not shown).

Referring to FIGS. 14 and 15, a third and fourth semiconductor devices 3 and 4 may be disposed to be spaced apart from the first and second semiconductor devices 1 and 2, respectively, in the first direction (e.g., the y-direction). The fourth semiconductor device 4 may be disposed over the third semiconductor device 3 in the third direction (e.g., the z-direction).

The third semiconductor device 3 may include a first unit semiconductor element 30a and a second unit semiconductor element 30b. The first semiconductor element 30a of the third semiconductor device 3 and the first unit semiconductor element 10a of the first semiconductor device 1 may include different write word lines 180a and 180c and different write bit lines 160a and 360a, respectively, while sharing the first read word line 122a and the first read bit line 124a. Similarly, the second unit semiconductor element 30b of the third semiconductor device 3 and the second unit semiconductor element 10b of the first semiconductor device 1 may include different write word lines 180b and 180d and different write bit lines 160b and 360b, respectively, while sharing a read word line (not shown) and a read bit line (not shown).

The fourth semiconductor device 4 may include a first unit semiconductor element 40a and a second unit semiconductor element 40b. The first unit semiconductor element 40a of the fourth semiconductor device 4 and the first unit semiconductor element 20a of the second semiconductor device 2 may include different write word lines 180a and 180c and different write bit lines 260a and 460a, respectively, while sharing a read word line (not shown) and a read bit line (not shown). Similarly, the second unit semiconductor element 40b of the fourth semiconductor device 4 and the second unit semiconductor element 20b of the second semiconductor device 2 may include different write word lines 180b and 180d and different write bit lines 260b and 460b, respectively, while sharing a read word line (not shown) and a read bit line (not shown).

In addition, the first unit semiconductor element 40a of the fourth semiconductor device 4 and the first unit semiconductor element 30a of the third semiconductor device 3 may include different write bit lines 360a and 460a, different read word lines (not shown), and different read bit lines (not shown), while sharing the write word line 180c. Similarly, the second unit semiconductor element 40b of the fourth semiconductor device 4 and the second unit semiconductor element 30b of the third semiconductor device 3 may include different write bit lines 360b and 460b, different read word lines (not shown), and different read bit lines (not shown), while sharing the write word lie 180d.

Referring to FIGS. 14 and 16, a fifth and a sixth semiconductor devices 5 and 6 may be disposed to be spaced apart from the first and second semiconductor devices 1 and 2, respectively, in the second direction (e.g., the x-direction). The sixth semiconductor device 6 may be disposed over the fifth semiconductor device 5 in the third direction (e.g., the z-direction).

The fifth semiconductor device 5 may include a first unit semiconductor element 50a and a second unit semiconductor element 50b. The first unit semiconductor element 50a of the fifth semiconductor device 5 and the first unit semiconductor element 10a of the first semiconductor device 1 may share the write bit line 160a, and may include different write word lines (not shown), different read word lines (not shown) and different read bit lines (not shown). The second unit semiconductor element 50b of the fifth semiconductor device 5 and the second unit semiconductor element 10b of the first semiconductor device 1 may share the write bit line 160b, but each may include different write word lines (not shown), different read word lines (not shown), and different read bit lines (not shown) from each other.

The sixth semiconductor device 6 may include a first unit semiconductor element 60a and a second unit semiconductor element 60b. The first unit semiconductor element 60a of the sixth semiconductor device 6 and the first unit semiconductor element 20a of the second semiconductor device 2 may share the write bit line 260a, but each may include different write word lines (not shown), different read word lines (not shown), and different read bit lines (not shown) from each other. The second unit semiconductor element 60b of the sixth semiconductor device 6 and the second unit semiconductor element 20b of the second semiconductor device 2 may share the write bit line 260b, but may include different write word lines (not shown), different read word lines (not shown), and different read bit lines (not shown) from each other.

Although not illustrated in FIGS. 14 to 16, a seventh and an eighth semiconductor devices 7 and 8 may be disposed to be spaced apart from the third and fourth semiconductor devices 3 and 4, respectively, in the second direction (e.g., the x-direction). The eighth semiconductor device 8 may be disposed over the seventh semiconductor device 7 in the third direction (e.g., the z-direction). The arrangement method of the seventh and eighth semiconductor devices 7 and 8 may be substantially the same as the arrangement method of the fifth and sixth semiconductor devices 5 and 6.

As described above, a semiconductor device U of FIGS. 14 to 16 may be a three-dimensional array of semiconductor devices 1-8 extending in the first to third directions. The semiconductor device U may include the semiconductor devices 1-8 having a three-dimensional structure described above with reference to FIGS. 4 to 13, thereby improving the degree of integration on the substrate.

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor device comprising a read transistor and a write transistor that are electrically connected to each other over a substrate,
wherein the read transistor comprises:
a read channel layer disposed on a plane over the substrate;
a read gate dielectric layer disposed over the read channel layer; and
a read gate electrode layer disposed over the read gate dielectric layer, and
wherein the write transistor comprises:
a write channel layer disposed over a portion of the read gate electrode layer;
a write bit line disposed on an upper surface of the write channel layer;
a write gate dielectric layer disposed on a side surface of the write channel layer; and
a write word line disposed to be adjacent to the write gate dielectric layer.

2. The semiconductor device of claim 1, wherein the read channel layer, the read gate dielectric layer, and the read gate electrode layer are disposed on a plane that is substantially parallel to a surface of the substrate.

3. The semiconductor device of claim 1, wherein a cross-sectional area of the read gate electrode layer is greater than a cross-sectional area of the write channel layer on a cross-sectional plane that is substantially parallel to the surface of the substrate.

4. The semiconductor device of claim 1, wherein the read gate electrode layer, the read gate dielectric layer, and the read channel layer are disposed to overlap with each other in a direction substantially perpendicular to the surface of the substrate.

5. The semiconductor device of claim 1, wherein the read gate dielectric layer comprises an antiferroelectric material.

6. The semiconductor device of claim 1, wherein the read gate dielectric layer comprises a paraelectric material having a high dielectric constant.

7. The semiconductor device of claim 1, further comprising a read word line and a read bit line that are respectively disposed at opposite ends of the read channel layer and that extend in a first direction substantially parallel to the surface of the substrate.

8. The semiconductor device of claim 7,
wherein the write bit line extends in a second direction substantially parallel to the surface of the substrate and perpendicular to the first direction, and
wherein the write word line extends in a third direction substantially perpendicular to the surface of the substrate.

9. The semiconductor device of claim 8, wherein a conductive carrier conducts in the second direction in the read channel layer, and the conductive carrier conducts in the third direction in the write channel layer.

10. A semiconductor device comprising first and second unit semiconductor elements that are disposed adjacent to each other over a substrate,
wherein the first unit semiconductor element comprises a first read transistor and a first write transistor that are electrically connected to each other,
wherein the second unit semiconductor element comprises a second read transistor and a second write transistor that are electrically connected to each other,
wherein a first read gate electrode layer of the first read transistor and a second read gate electrode layer of the second read transistor are disposed to be spaced apart from each other in a direction substantially perpendicular to a surface of the substrate, and
wherein a first write channel layer of the first write transistor and a second write channel layer of the second write transistor are disposed between the first read gate electrode layer and the second read gate electrode layer in the direction substantially perpendicular to the surface of the substrate.

11. The semiconductor device of claim 10, wherein the first and second unit semiconductor elements are electrically separated from each other.

12. The semiconductor device of claim 10, wherein each of the first and second write channel layers extends in the direction substantially perpendicular to the surface of the substrate.

13. The semiconductor device of claim 10,
wherein the first and second write channel layers are disposed to be spaced apart from each other along a direction substantially parallel to the surface of the substrate; and
wherein the first write channel layer is disposed to partially overlap with the second write channel layer along the direction substantially parallel to the surface of the substrate.

14. The semiconductor device of claim 10, wherein the first and second read gate electrode layers are disposed to overlap with each other along the direction substantially perpendicular to the surface of the substrate.

15. The semiconductor device of claim 10,
wherein on a cross-section substantially parallel to the surface of the substrate, a cross-sectional area of the first read gate electrode layer is greater than a cross-sectional area of the first write channel layer, and
wherein on a cross-section substantially parallel to the surface of the substrate, a cross-sectional area of the second read gate electrode layer is greater than a cross-sectional area of the second write channel layer.

16. The semiconductor device of claim 10, wherein on a cross-section substantially parallel to the surface of the substrate, a cross-sectional area of the first read gate electrode layer or a cross-sectional area of the second read gate electrode layer is greater than a sum of a cross-sectional area of the first write channel layer and a cross-sectional area of the second write channel layer.

17. The semiconductor device of claim 10, further comprising:
a first write bit line disposed on the first write channel layer and extending in the direction substantially parallel to the surface of the substrate; and
a second write bit line disposed on the second write channel layer and extending in a direction substantially parallel to the surface of the substrate,
wherein the first write bit line is disposed across the second read gate electrode layer, and the second write bit line is disposed across the first read gate electrode layer.

18. The semiconductor device of claim 10,
wherein the first read transistor comprises:
a first read channel layer disposed on a plane substantially parallel to the surface of the substrate;
a first read gate dielectric layer disposed over the first read channel layer;
the first read gate electrode layer disposed over the first read gate dielectric layer; and
a first read word line and a first read bit line that are respectively disposed in contact with opposite side surfaces of the first read channel layer and extend in a first direction substantially parallel to the surface of the substrate, and
wherein the first write transistor comprises:
the first write channel layer disposed over a portion of the first read gate electrode layer;
a first write bit line disposed on an upper surface of the first write channel layer and extending in a second direction substantially parallel to the surface of the substrate;
a first write gate dielectric layer disposed on a side surface of the first write channel layer; and
a first write word line extending in a third direction substantially perpendicular to the surface of the substrate, on the first write gate dielectric layer.

19. The semiconductor device of claim 18,
wherein the second read transistor comprises:
a second read channel layer disposed on a plane substantially parallel to the surface of the substrate;
a second read gate dielectric layer disposed over the second read channel layer;
the second read gate electrode layer disposed over the second read gate dielectric layer; and
a second read word line and a second read bit line that are respectively disposed in contact with opposite side surfaces of the second read channel layer and extending in the first direction, and
wherein the second write transistor comprises:
the second write channel layer disposed over a portion of the second read gate electrode layer;
a second write bit line disposed on an upper surface of the second write channel layer and extending in the second direction;
a second write gate dielectric layer disposed on a side surface of the second write channel layer; and
a second write word line extending in the third direction on the second write gate dielectric layer.

20. The semiconductor device of claim 19, further comprising third and fourth unit semiconductor elements disposed to be spaced apart from the first and second unit elements in the first direction, respectively,
wherein the third unit semiconductor element and the first unit semiconductor element share the first read word line and the first read bit line, and each includes different write word lines and different write bit lines from each other, and
wherein the fourth unit semiconductor element and the second unit semiconductor element share the second read word line and the second read bit line, and each includes different write word lines and different write bit lines from each other.

21. The semiconductor device of claim 19, further comprising third and fourth unit semiconductor elements disposed to be spaced apart from the first and second unit elements in the second direction, respectively,
wherein the third unit semiconductor element and the first unit semiconductor element share the first write bit line, and each includes different write word lines, different read word lines, and different read bit lines from each other, and
wherein the fourth unit semiconductor element and the second unit semiconductor element share the second write bit line, and each includes different write word lines, different read word lines, and different read bit lines from each other.

22. The semiconductor device of claim 19, further comprising third and fourth unit semiconductor elements disposed to be spaced apart from the first and second unit elements in the third direction, respectively,
wherein the third unit semiconductor element and the first unit semiconductor element share the first write word line, and each includes different write bit lines, different read word lines, and different read bit lines, and
wherein the fourth unit semiconductor element and the second unit semiconductor element share the second write word line, and each includes different write bit lines, different read word line, and different read bit lines from each other.
